(19) United States
(12) Patent Application Publication
(10) Pub. No.: US 2026/0262489 A1
(43) Pub. Date: Sep. 3, 2026

(54) MULTILAYER HEAT SINKS

(71) Applicant: University of Maine System Board of Trustees, Orono, ME (US)

(72) Inventor: Sharmila Mukhopadhyay, Holden, ME (US)

(21) Appl. No.: 19/163,462

(22) PCT Filed: Mar. 14, 2024
(86) PCT No.: PCT/US24/19913

§ 371 Date: Sep. 9, 2025

Related U.S. Application Data
(60) Provisional application No. 63/452,013, filed on Mar. 14, 2023.

(51) Int. Cl. H10W 40/22; C23C 16/02; C23C 16/26; H10N 10/13; H10W 40/00; H10W 40/20; H10W 40/25; H10W 40/40

(52) U.S. Cl. CPC H10W 40/226; C23C 16/0227; C23C 16/0272; C23C 16/26; H10W 40/037; H10W 40/242; H10W 40/258; H10W 40/259; H10W 40/40; H10N 10/13

(57) ABSTRACT

Structural hierarchy in heat sinks combines the thermal conductivity of materials with fin architectures tailored for active or passive electronic cooling components. Heat sinks with nanoscale hierarchical structures can combine thermally conductive materials with high aspect-ratio fms for rapid thermal exchange with surroundings. Carbon nanotubes (CNT) are promising components since they combine ultra-high thermal conductivity along their axial directions with high surface area and radiative heat transfer capacity. In some embodiments, nanostructures (e.g., aligned carbon nanotubes) strongly attached (e.g., covalently attached) to surfaces of structures such as heat sinks, heat spreaders, etc., can enhance thermal performance (e.g., thermoelectric energy generation (TEG) voltage, heat dissipation, heat radiation, etc.).

### CROSS-REFERENCE TO RELATED APPLICATIONS

This application claims priority to and benefit of U.S. Provisional Patent No. 63/452,013, filed Mar. 14, 2023, the disclosure of which is incorporated by reference herein in its entirety.

### GOVERNMENT SUPPORT

This invention was made with government support under Award DE SC0020126 awarded by the U.S. Department of Energy, Office of Science, Office of Basic Energy Sciences Established Programs to Stimulate Competitive Research (EPSCoR). The government has certain rights in the invention.

### BACKGROUND

The rapid development of miniaturized electronics and energy harvesting devices such as thermoelectric generators (TEG) have created high demand for advanced heat sink (HS) materials. TEG units or modules contain multiple pairs of p-type and n-type semiconductors with opposing Seebeck coefficients stacked together for converting the temperature difference between two sides into a voltage output, without the need for moveable parts or chemicals. The open circuit voltage of a TEG is the most direct indicator of the temperature difference between the two sides, and depends on the effective Seebeck coefficient of the module, and the temperatures of the hot and cold sides of the TEG. Engineering efforts are directed at increasing the heat transfer between the hot and cold sides to improve the performance and efficiency of heat sinks and heat spreaders.

### SUMMARY

The present embodiments take advantage of the properties of nanostructures with high surface areas, high thermal conductivity, and high emissivity that are attached to the surfaces of thermal conductors to enhance their heat transfer properties. In some embodiments, carbon nanotubes (CNTs) are covalently attached with their axes aligned normal to the surfaces of copper heat sinks by chemical vapor deposition (CVD) growth with an oxide catalyst layer. In some embodiments, such CNTs act as nanostructured fins or radiators that can enhance the performance of prefabricated heat sinks without impacting weight, volume, or shape formability. The present disclosures provide, inter alia, insight into how carbon nanotube arrays can be aligned normal to uneven copper surfaces for optimized heat sink applications.

In one aspect, the present embodiments are directed to a multilayer structure comprising: a substrate; an intermediate layer coating a surface of the substrate; and a plurality of nanoscale attachments attached to the intermediate layer or to the surface of the substrate.

In some embodiments, the substrate comprises a material with high thermal conductivity (e.g., above 10 W m⁻¹ K⁻¹, above 50 W m⁻¹ K⁻¹, above 100 W m⁻¹ K⁻¹). In some embodiments, the substrate comprises a metal (e.g., copper, aluminum, brass). In some embodiments, the substrate comprises a ceramic (e.g., aluminum nitride, beryllium oxide, aluminum oxide, diamond, silicon carbide, silica). In some embodiments, the substrate comprises at least one of a sheet, a porous structure, a block, a heat sink, a heat spreader, a wire, a rod, foil, a mesh, or a tube. In some embodiments, the substrate comprises a heat sink, wherein the heat sink comprises one or more fins and/or one or more pins for heat dissipation.

In some embodiments, the plurality of nanoscale attachments comprise carbon nanotubes. In some embodiments, the carbon nanotubes are arranged in a substantially vertically aligned array, wherein each of the carbon nanotubes is strongly (e.g., covalently) attached at one end to a location on the intermediate layer or on the substrate, and wherein the axes of the carbon nanotubes are aligned substantially normal to the substrate surface at the location of attachment. In some embodiments, each of the carbon nanotubes comprises an outer diameter between about 5 nm and about 30 nm (e.g., between about 5 nm and 20 nm, between about 10 nm and 40 nm, between about 15 nm and 30 nm, between about 0.5 nm and 2 nm, between about 0.5 nm and 5 nm), and a length between about 5 μm and 60 μm (e.g., between about 50 μm to about 60 μm, between about 1 μm to about 100 μm, between about 1 μm to about 500 μm, between about 1 μm to about 1000 μm).

In some embodiments, the plurality of nanoscale attachments are strongly (e.g., covalently) bonded to the intermediate layer. In some embodiments, the carbon nanotubes comprise an average areal density of about 1.5×10¹⁰ nanotubes per square centimeter (e.g., about 10⁹ nanotubes per cm², about 10¹⁰ nanotubes per cm², about 5×10¹⁰ nanotubes per cm², about 10¹¹ nanotubes per cm², between about 5×10⁹ nanotubes per cm² and about 5×10¹⁰ nanotubes per cm²).

In some embodiments, the intermediate layer comprises an oxide. In some embodiments, the oxide comprises silicon dioxide or aluminum oxide. In some embodiments, the oxide layer is between about 10 nm and 20 nm thick (e.g., between about 5 nm and 10 nm, between about 5 nm and 20 nm, between about 10 nm and 40 nm, below about 50 nm, between about 1 nm and 100 nm).

In another aspect, the present embodiments are directed to a method of fabricating a multilayer structure, comprising: providing a substrate; preparing an outer surface of the substrate using one or more surface treatments; at least partially coating the outer surface with an intermediate layer to form a coated surface; and depositing a plurality of nanoscale attachments onto the coated surface.

In some embodiments, the one or more surface treatments comprises cleaning, treating, and/or activating using ions, acids, alkalis, plasmas, and/or solvents.

In some embodiments, the plurality of nanoscale attachments comprise carbon nanotubes. In some embodiments, the carbon nanotubes are arranged in a substantially vertically aligned array, wherein each of the carbon nanotubes is strongly (e.g., covalently) attached at one end to the outer surface of the intermediate layer.

In some embodiments, coating the outer surface comprises using at least one of plasma deposition, liquid deposition, atomic layer deposition (ALD), sol-gel deposition, or chemical vapor deposition (CVD). In some embodiments, depositing the plurality of nanoscale attachments comprises using at least one of plasma deposition, liquid deposition, atomic layer deposition (ALD), or chemical vapor deposition (CVD).

In some embodiments, the coating the outer surface further comprises heating the substrate in a controlled environment. In some embodiments, depositing the plurality of nanoscale attachments further comprises heating the substrate in a controlled environment.

In some embodiments, the intermediate layer comprises an oxide. In some embodiments, the oxide comprises silicon dioxide or aluminum oxide.

In some embodiments, the nanoscale attachments comprise at least one of nanotubes of ceramics, nanotubes of nitrides, nanotubes of oxides, carbon nanotubes coated with nitrides and/or oxides, or nanoparticles of metals and/or ceramics.

In some embodiments, the substrate comprises a material with high thermal conductivity (e.g., above 10 W m⁻¹ K⁻¹, above 50 W m⁻¹ K⁻¹, above 100 W m⁻¹ K⁻¹). In some embodiments, the material comprises a metal (e.g., copper, aluminum, brass). In some embodiments, the material comprises a ceramic (e.g., aluminum nitride, beryllium oxide, aluminum oxide, diamond, silicon carbide, silica).

In some embodiments, the substrate comprises at least one of a sheet, a porous structure, a block, a heat sink, a heat spreader, a wire, a rod, foil, a mesh, or a tube. In some embodiments, the plurality of nanoscale attachments forms a continuous, conformal layer.

In some embodiments, depositing comprises using floating catalyst chemical vapor deposition (FC-CVD). In some embodiments, FC-CVD is conducted using a three-zone programmable thermal furnace, comprising the steps of: beating the substrate after coating with a silica layer to 700° C. under inert gas (e.g., Ar gas environment); growing carbon nanotubes at 700° C. for 3 hours with xylene as a carbon source and ferrocene as a catalyst; and cooling down to room temperature under inert gas (e.g., Ar gas environment).

In some embodiments, the substrate comprises copper.

In some embodiments, coating the outer surface comprises microwave plasma deposition, comprising the steps of: etching the substrate with oxygen; depositing silica using a mixture of hexa-methyldisiloxane (HMDSO) and oxygen; and stabilizing with oxygen.

In some embodiments, etching the substrate occurs at 225 W power for 180 s, and depositing silica occurs at 300 W power for 300 s, wherein depositing silica occurs with HMDSO flowing at 2 ml/min and oxygen flowing at 48 ml/min, and wherein stabilizing with oxygen occurs at ambient temperature and 150 W power for 60 s. In some embodiments, the steps depositing silica are repeated for a total of two cycles (e.g., three cycles, four cycles, five cycles).

In another aspect, the present embodiments are directed to a method of cooling a structure, comprising thermally contacting a surface of the structure with a multilayer structure according to any of the embodiments disclosed herein, comprising: a substrate; an intermediate layer coating a surface of the substrate; and a plurality of nanoscale attachments attached to the intermediate layer or to the surface of the substrate.

In some embodiments, the method further comprises flowing a fluid around the plurality of nanoscale attachments. In some embodiments, the fluid comprises at least one of air, water, gas, solvent, coolant, or nanofluid. In some embodiments, flowing the fluid comprises forcing the fluid to flow.

In some embodiments, the structure to be cooled comprises at least one of a thermoelectric generator, a processor, a central processing unit (CPU), a GPU, a chipset, a random access memory (RAM) module, a laser, a light emitting diode (LED), a battery, a photovoltaic, a computer, a chip, a power electronic module, a thermoelectric cooler, a motor, an engine, an actuator, a mobile device, a tablet, a mobile phone, a part of an automobile, or a part of a vehicle.

In some embodiments, the method further comprises applying a layer of a thermally conductive interface between the structure to be cooled and the multilayer structure, wherein the thermally conductive interface comprises at least one of a thermal paste, a thermal compound, a thermal grease, a thermal interface material, a thermal gel, a heat paste, a heat sink compound, a heat sink paste, or a CPU grease.

In another aspect, the present embodiments are directed to a system comprising: a structure to be cooled; and a multilayer structure according to any one of the embodiments described herein, wherein the multilayer structure is configured to be in thermal contact with the structure to be cooled.

In some embodiments, the structure to be cooled comprises at least one of a thermoelectric generator, a processor, a central processing unit (CPU), a GPU, a chipset, a random access memory (RAM) module, a laser, a light emitting diode (LED), a battery, a photovoltaic, a computer, a chip, a power electronic module, a thermoelectric cooler, a motor, an engine, an actuator, a mobile device, a tablet, a mobile phone, a part of an automobile, or a part of a vehicle.

In some embodiments, the system further comprises a fluid that flows around the plurality of nanoscale attachments, wherein the fluid comprises at least one of air, water, gas, solvent, coolant, or nanofluid.

In some embodiments, the system further comprises a thermally conductive interface layer disposed between the structure to be cooled and the multilayer structure, wherein the thermally conductive interface layer comprises at least one of a thermal paste, a thermal compound, a thermal grease, a thermal interface material, a thermal gel, a heat paste, a heat sink compound, a heat sink paste, or a CPU grease.

In some embodiments, the thermoelectric generator is thermally contacted by the multilayer structure on a cold side of the thermoelectric generator, and wherein the thermoelectric generator is configured to thermally contact the structure to be cooled on a hot side of the thermoelectric generator.

### BRIEF DESCRIPTION OF THE DRAWING

The present teachings described herein will be more fully understood from the following description of various illustrative embodiments, when read together with the accompanying drawing. It should be understood that the drawing described below is for illustration purposes only and is not intended to limit the scope of the present teachings in any way.

FIG. 1 is a schematic diagram illustrating different cooling technologies for thermoelectric generator (TEG) systems.

FIG. 2 is a schematic diagram illustrating a hierarchical hybrid nanomaterial heat sink structure and measurement setup, according to aspects of the present embodiments.

FIG. 3A is a photograph of a thermoelectric device with flat copper sheet beat sink coated in CNT (left) and a thermoelectric device with flat copper sheet heat sink without CNT coating (right), according to aspects of the present embodiments.

FIG. 3B is a photograph of a thermoelectric device with finned copper heat sink without CNT coating (left) and a thermoelectric device with finned copper heat sink coated in CNT (right), according to aspects of the present embodiments.

FIG. 3C is a photograph of a copper sheet (left) and a photograph of a copper sheet with CNT coating grown on it (right), according to aspects of the present embodiments.

FIG. 3D is a photograph of a commercial copper heat sink with skived fin structure (left), and a photograph of the same heat sink coated with CNT (right), according to aspects of the present embodiments.

FIG. 4A is a scanning electron microscopy (SEM) image of a CNT carpet grown on copper in cross-sectional view at low magnification, according to aspects of the present embodiments.

FIG. 4B is a scanning electron microscopy (SEM) image of a CNT coating grown on copper in cross-sectional view at high magnification, according to aspects of the present embodiments.

FIG. 4C is a scanning electron microscopy (SEM) image of a side view of a CNT coating grown on a copper film on a silicon wafer (top), and in an enlarged view (bottom) showing substantially aligned CNTs, according to aspects of the present embodiments.

FIG. 4D is a scanning electron microscopy (SEM) image of a top view of a CNT coating grown on a copper film showing some degree of CNT entanglement, according to aspects of the present embodiments.

FIG. 5 is a graph of output voltage as a function of time for different heat sink arrangements when the heater temperature is increased from ambient temperature (21° C.) up to and held at 100° C., according to aspects of the present embodiments.

FIG. 6 shows a plot of cold side temperatures on a TEG for different heat sink arrangements when T_{H} is maintained at 180° C., according to aspects of the present embodiments.

FIG. 7 shows a plot of open circuit voltage output from a TEG with different heat sink arrangements when T_{H} is maintained at 180° C., according to aspects of the present embodiments.

### DEFINITIONS

In order for the present invention to be more readily understood, certain terms are first defined below. Additional definitions for the following terms and other terms are set forth throughout the specification. The publications and other reference materials referenced herein to describe the background of the invention and to provide additional detail regarding its practice are hereby incorporated by reference.

The articles “a” and “an” are used herein to refer to one or to more than one (i.e., to at least one) of the grammatical object of the article. By way of example, “an element” means one element or more than one element.

Approximately or about: As used herein, the terms “approximately” or “about,” as applied to one or more values of interest, refers to a value that is similar to a stated reference value. In certain embodiments, the terms “approximately” or “about” refers to a range of values that fall within 25%, 20%, 19%, 18%, 17%, 16%, 15%, 14%, 13%, 12%, 11%, 10%, 9%, 8%, 7%, 6%, 5%, 4%, 3%, 2%, 1%, or less in either direction (greater than or less than) of the stated reference value unless otherwise stated or otherwise evident from the context (except where such number would exceed 100% of a possible value).

Carbon nanotube (CNT): As used herein, the term “carbon nanotube” refers to a nanoscale structure of one or more layers of carbon atoms arranged in a graphitic lattice rolled into a cylinder or tube. In some embodiments, a CNT may be a single-walled carbon nanotube (SWNT or SWCNT), a double-walled carbon nanotube (DWNT or DWCNT), or a multi-walled carbon nanotube (MWNT or MWCNT). In double-walled and multi-walled carbon nanotubes, the nanotubes are arranged coaxially. In some embodiments, the outer diameters of CNTs may range from about 0.5 nm to about 30 nm, or up to about 100 nm. In some embodiments, the lengths of CNTs may range from nanometers up to hundreds of micrometers or multiple centimeters.

Heat sink or heatsink: As used herein, the term “heat sink” or “heatsink” refers to a structure or a device that is a passive heat exchanger, which transfers heat from a heat source to a surrounding fluid medium (e.g., a coolant, a fluid, a gas, ambient air, etc.). In some embodiments, heat sinks are used to cool electronic devices such as processors, CPUs, GPUs, chipsets, RAM modules, lasers, LEDs, batteries, photovoltaics, computers, chips, power electronics, etc. In some embodiments, a heat sink includes various physical structures to increase the surface area that is in contact with the surrounding fluid medium. In some embodiments, the structures to increase surface area includes fins, protrusions, pins, cavities, etc. In some embodiments, heat sinks are made of thermally conductive materials such as metals (e.g., copper, aluminum, aluminum alloys, brass, etc.) and/or ceramics (e.g., aluminum nitride, beryllium oxide, aluminum oxide, silicon carbide, diamond, etc.).

Heat spreader: As used herein, the term “heat spreader” refers to a structure or device that transfers heat from a region of higher temperature to a region of lower temperature. In some embodiments, heat spreaders may be passive or active. In some embodiments, passive heat spreaders may include a block of material with high thermal conductivity. In some embodiments, active heat spreaders may include an external energy source to speed up heat transfer.

Nanofluid: As used herein, the term “nanofluid” refers to a fluid that contains nanometer-scale particles that may be suspended in a colloid in a base fluid. In some embodiments, particles in a nanofluid may include one or more structures such as metals, oxides, carbides, nanotubes, etc. In some embodiments, the base fluid may include water, ethylene glycol, or oil. In some embodiments, nanofluids may be useful in applications in heat transfer.

Nanomaterial and nanostructure: As used herein, the terms “nanomaterial” and “nanostructure” refer to materials and structures where key components have at least one dimension scaled between about 1 and about 100 nm (i.e., nanoscaled). In some embodiments, other dimensions of nanomaterials and nanostructures may be larger than nanoscale. In some embodiments, nanomaterials may contain nanostructured components and non-nanostructured components. In some embodiments, the terms nanomaterial and nanostructure may be used interchangeably. In some embodiments, the term nanomaterial may refer to a larger bulk material that contains nanostructured components. In some embodiments, the term nanostructure may refer to a single nanoscale component.

Thermoelectric generator (TEG): As used herein, the term “thermoelectric generator” refers to a solid-state device that uses the Seebeck effect to convert heat (i.e., temperature differences) into electrical energy. In some embodiments, TEGs may include thermoelectric materials, thermoelectric modules, and thermoelectric systems. In some embodiments, the efficiency of a thermoelectric material is given by its figure of merit ZT=S²σT/κ, where S is the Seebeck coefficient of the material, σ is the electrical conductivity, and κ is the thermal conductivity. In some embodiments, TEGs are made of one or more pairs of p-doped and n-doped semiconductors of different Seebeck coefficients. In some embodiments, a temperature difference between a hot side and a cold side of a TEG is associated with a voltage drop between the hot side and the cold side. In some embodiments, the cold side of a TEG may be thermally contacted with additional heat dissipation elements (e.g., heat sinks, heat spreaders, coolant fluids, etc.) to transport away heat.

Throughout this disclosure, various aspects of the invention can be presented in a range format. It should be understood that the description in range format is merely for convenience and brevity and should not be construed as an inflexible limitation on the scope of the invention. Accordingly, the description of a range should be considered to have specifically disclosed all the possible subranges as well as individual numerical values within that range. For example, description of a range such as from 1 to 6 should be considered to have specifically disclosed subranges such as from 1 to 3, from 1 to 4, from 1 to 5, from 2 to 4, from 2 to 6, from 3 to 6 etc., as well as individual numbers within that range, for example, 1, 2, 2.7, 3, 4, 5, 5.3, and 6. This applies regardless of the breadth of the range.

### DETAILED DESCRIPTION OF CERTAIN EMBODIMENTS

It is contemplated that methods, systems, compositions, and processes of the claimed invention encompass variations and adaptations developed using information from the embodiments described herein. Adaptation and/or modification of the methods, systems, compositions, and processes described herein may be performed, as contemplated by this description.

Throughout the description, where methods, systems, compositions, and processes are described as having, including, or comprising specific components, or where processes and methods are described as having, including, or comprising specific steps, it is contemplated that, additionally, there are compositions of the present invention that consist essentially of, or consist of, the recited components, and that there are processes and methods according to the present invention that consist essentially of, or consist of, the recited steps.

It should be understood that the order of steps or order for performing certain action is immaterial so long as the invention remains operable. Moreover, two or more steps or actions may be conducted simultaneously.

The mention herein of any publication, for example, in the Background section, is not an admission that the publication serves as prior art with respect to any of the claims presented herein. The Background section is presented for purposes of clarity and is not meant as a description of prior art with respect to any claim.

Headers are provided for the convenience of the reader; the presence and/or placement of a header is not intended to limit the scope of the subject matter described herein.

### A. Cooling Technologies and Thermoelectric Devices

Solid heat sink (HS) designs are aimed at maximizing heat transfer through (i) conduction, which depends on thermal conductivity of the material (K), (ii) convection, which depends on heat transfer coefficient and surface area exposed, and (iii) radiation, which depends on surface area and thermal emissivity. High K materials are needed for HS, and copper is the preferred metal for most applications. In addition to conductivity, the structural hierarchy of HS designs are important for extending their surface into a surrounding fluid (e.g., gas, liquid) through fins (i.e., radiators). That is, the use of physical structures of different dimensions to achieve varying degrees of thermal contact and surface area is beneficial. In advanced HS designs, the fins may be further enhanced with contoured shapes, grooves, and/or perforations. Cooling may be further enhanced by forcing air, water or other coolants including nanofluids through, around, or between HS structures.

Graphene-based nanomaterials are some of the highest thermal conductivity solids known, and carbon nanotubes (CNTs) combine the ultra-high thermal and electrical conductivity of planar graphene along their axial direction with ultra-high specific surface area available for convective heat transfer. CNTs are also near-perfect blackbody radiators (i.e., with emissivity over 99% in most wavelengths) and hence suitable for radiative cooling. They have been successfully used in nanofluids as coolants and in composite fillers. However, such designs involving CNTs embedded in a matrix phase do not make full use of the ultra-high surface area and high radiative emissivity of CNT.

The open circuit voltage of a TEG is the most direct indicator of the temperature difference between the two sides and is given by equation (1):

$${V}_{out} = S ( {T}_{H} - {T}_{C} ) \qquad ( 1 )$$

where Vₒᵤₜ is the voltage output, S is the effective Seebeck coefficient of the module (in units of V/K), and T_{H} and T_{C} are the temperatures of the hot and cold sides (K), respectively. When the hot side is attached to a heat source of a certain temperature, increasing heat transfer from the cold side is the most easily controllable parameter that can minimize T_{C} and maximize Vₒᵤₜ.

The theoretical thermoelectric conversion efficiency of TEG systems (η_{TE}) also depend on the operating temperature difference along with the figure of merit (Z\tilde{T}), given by equation (2):

$${η}_{TE} = ( \frac{{T}_{H} - {T}_{C}}{{T}_{H}} ) ( \frac{\sqrt{1 + Z \overline{T}} - 1}{\sqrt{1 + Z \overline{T}} + ( {T}_{C} / {T}_{H} )} \qquad ( 2 )$$

where the figure of merit Z\tilde{T} is determined by the thermoelectric module design, and is given by equation (3):

$$Z \overline{T} = ( {S}^{2} \overline{T} / ρκ ) \qquad ( 3 )$$

where S (mV/K) is the effective Seebeck coefficient, ρ(Ω·m) is the electrical resistivity, and κ(W/m·K) is the thermal conductivity. This has some dependence on the average or “effective” temperature of the module

$$( \overline{T} = \frac{1}{2} ( {T}_{H} + {T}_{C} ) ) ,$$

but is mostly determined by the material parameters.

The present disclosure encompasses the recognition that for a given TEG module in any application, a controllable process parameter to maximize its performance is to minimize the T_{c}. Cooling methods and heat sink designs on the cold side of the TEG are therefore extremely important for future growth of green energy technology.

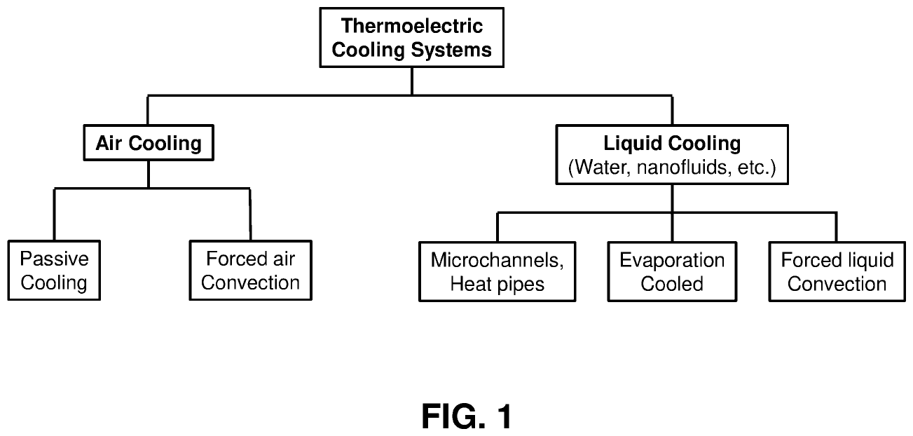

Thermoelectric cooling components can be cooled using any application-appropriate fluid (e.g., liquid or gas). For example, in some embodiments, thermoelectric cooling components can be air cooled or water/liquid cooled and commonly used options for small-mid size generator systems can be classified as shown in FIG. 1, which is a diagram illustrating different cooling technologies for thermoelectric generator (TEG) systems.

Passive cooling systems exchange heat with surroundings by natural ventilation. In contrast, active cooling systems involve either fans or liquid coolants such as water, organic solvents or nanocomponents suspended in fluids. Passive cooling is typically considered the most economical and energy-efficient option since forced air or liquid would need additional energy for circulation, and add additional components to the TEG system. In accordance with various embodiments, it is also possible to design heat sinks that can normally operate in passive mode, but provide the option of adding active coolants in more demanding service conditions.

Heat sink architectures are aimed at maximizing thermal flux (\dot{Q} in W or J·s⁻¹) between the solid surface and surrounding medium by the three general heat transfer pathways at every point of the heat sink solid surface. Conduction loss is given by equation (4):

$${\dot{Q}}_{conduction} = - κ A \frac{Δ T}{Δ x} \qquad ( 4 )$$

where κ is the thermal conductivity of the material (W/m·K) and ΔT/Δx is the temperature gradient across the solid (K·m⁻¹), and A(m²) is the cross-sectional area across the heat flux direction.

Convection loss is given by equation (5):

$${\dot{Q}}_{convection} = hA ( {T}_{s} - {T}_{f} ) \qquad ( 5 )$$

where Tₛ is the surface temperature and T_{f} is the fluid (air) temperature in Kelvin, which depends on heat transfer coefficient at that point (h in W/m²·K) and surface area of interaction (A in m²).

Radiation loss is given by equation (6):

$${\dot{Q}}_{radiation} = σ {eAT}^{4} \qquad ( 6 )$$

where σ is the Stefan-Boltzmann constant (W·m⁻²·K⁻⁴), which depends on surface area (A), thermal emissivity (e) (0<e<1) and T is the object's absolute temperature (K).

It can be seen from these equations that heat sinks need high conductivity materials along with structural hierarchy to extend the solid surface into the surrounding fluid, e.g., through the inclusion of fins (radiators), i.e., by providing more surface area through which heat transfer can occur.

Regarding heat sink material, copper and aluminum are the most common heat sink (HS) metals. Finned architectures can be made with metals by skiving technology that pares off thin layers and turns them upwards, resulting in a seamless monolithic solid with fin-like architectures. Aluminum is lighter than copper, but also has lower thermal conductivity. The thermal conductivities of aluminum and copper are, respectively, 237 W m⁻¹ K⁻¹ and 401 W m⁻¹ K⁻¹. In some embodiments, copper is the preferred metal for high-end electronic devices due to its higher thermal conductivity, corrosion resistance, and durability in high temperatures.

However, the thermal transport of even the best copper heat sinks is ultimately limited by one or more factors including the fin architecture, size and weight that can be tolerated in the overall design. This has resulted in large number of studies on heat sink designs through shape contouring, often in combination with grooves, perforations, and fluid flow technologies. Different types of passive and active cooling techniques to optimize heat sink performance have been summarized in review articles. Some studies have focused specifically on nanofluids for improving TEG performance. Others have focused on experimental and numerical analyses for multi-objective optimization of heat sink perforations for increasing convective heat transfer for TEG systems. The trend shown by earlier studies is that improving heat sink design can increase the TEG performance by 5-10% though passive cooling, and up to 15-20% through additional forced convection involving fans, coolants and nanofluids, the latter requiring coolant hardware and controls to be added to the overall TEG system.

In some embodiments, provided structures and methods may be applied to heat sinks and/or heat spreaders. In some embodiments, provided structures and methods may be applied to heat sinks and/or heat spreaders made of a metal (e.g., copper, aluminum, aluminum alloy, brass, etc.). In some embodiments, provided structures and methods may be applied to heat sinks and/or heat spreaders made of a ceramic (e.g., aluminum nitride, beryllium oxide, aluminum oxide, diamond, silicon carbide, silica, etc.). In some embodiments, provided structures and methods may be applied to substrates that may be at least one of sheet, a porous structure, a block, a heat sink, a heat spreader, a wire, a rod, foil, a mesh, a tube, etc.

In some embodiments, provided structures and methods may improve the passive cooling performance of heat sinks by introducing nanoscale materials with high surface area and increased heat transport pathways to the surfaces of heat sinks, without significant increase in weight, size, or additional system components. Nanostructures such as graphene-based nanostructures such as carbon nanotubes (CNTs) have extremely high thermal conductivities (e.g., over 3000 W m⁻¹ K⁻¹) along their axial directions and have ultra-high specific surface area available for convective heat transfer (e.g., over 1000 m²/g). CNTs are also near-perfect blackbody radiators (with emissivity over 99% in most wavelengths) and hence they can enhance radiative cooling. They have been successfully used in improving thermal conductivity in nanofluid coolants, composite materials, and coatings. However, unlike the structures and methods provided herein, most designs involving CNTs dispersed in matrix phases do not make full use of the ultra-high surface area and high radiative emissivity of isolated CNTs anchored to heat-spreading surfaces.

In some embodiments, provided structures and methods focus on complete utilization of the advantages of CNTs (i.e., their high axial thermal conductivities, high specific surface areas, and high radiative emissivity) through hierarchical hybrid materials comprising of arrays of CNTs strongly attached (e.g., covalently attached) at one end and aligned normal to copper heat fin surfaces. By adding the advantages of CNTs, which act as “nano fins” and “nano radiators”, to prefabricated heat sinks, their performance may be enhanced without impacting weight, volume, or shape formability.

### B. Experimental Methods

### CNT Fabrication on Copper Substrates

While several methods can be used synthesize nanotubes, rapid production approaches such as arc discharge and laser ablation typically produce nanotubes in random orientations that have to be aligned during device assembly or fabrication using either electrophoretic methods or mechanical strain. In some embodiments, in order to fabricate strongly bonded (e.g., covalently bonded) CNTs on a substrate that are also aligned along pre-determined orientations during growth, chemical vapor deposition (CVD) methods are used. There have been prior studies of attaching vertically aligned (i.e., normal to growth substrate) CNTs on silicon and other metals for a variety of applications including thermal management, and growing CNTs on copper has also been attempted using different techniques. CNTs may be grown. in some embodiments, by water-vapor-assisted CVD on copper. Multiwalled CNTs on copper have been deposited after sputter-deposition of one or more films of metal catalysts using thermal CVD and/or microwave plasma CVD. An additional study reported CVD growth on copper sheet after first coating the surface with alumina film and an additional layer of iron catalyst using a combination of atomic layer deposition and e-beam deposition, but the durability of the CNT coating and the feasibility of using these approaches for complex and uneven heat sink architectures were unknown. The attachment of CNTs on carbon materials with complex geometries using non-line-of sight and scalable surface processing techniques has been demonstrated and produced durable, covalently attached “carpets” of CNTs, but the approach has not been applied to copper substrates.

In some embodiments, provided structures and methods include growing CNT arrays that are aligned normal to uneven copper surfaces for improving TEG performance. In some embodiments, provided structures and methods also include methods of design, fabrication, and testing of robust materials that may enhance the performance of TEG heat sinks in ambient passive conditions without the need for forced fluid coolants. Success in this approach enables additional design of hierarchical hybrid Cu-CNT materials customized for portable, lightweight and/or remote heat exchanger devices. In some embodiments, other materials with high thermal conductivities (e.g., metal, aluminum, ceramics, aluminum nitride, beryllium oxide, aluminum oxide, diamond, silicon carbide, silica, etc.) may be used as substrate materials onto which nanostructured materials with high conductivity, high specific surface area, and high thermal emissivity may be strongly (e.g., covalently) attached.

In some embodiments, substrate materials may be or comprise any of a variety of shapes (e.g., flat sheets, porous structures, blocks, heat sinks, heat spreaders, wires, rods, foils, meshes, tubes, etc.). In some embodiments, a substrate material may include a flat, polished sheet of pure copper (0.68 mm thick). In some embodiments, a substrate material may include a commercial copper heat sink (e.g., 40 mm×40 mm×10 mm, pure copper skived fin heat sink supplied by GC Thermal).

In some embodiments, the growth of vertically aligned (e.g., normally aligned) carbon nanotubes on copper (or another thermally conductive substrate) may be performed by a floating catalyst chemical vapor deposition (FC-CVD) technique. The FC-CVD technique is a non-line-of-sight approach that is applicable to uneven substrates and may be scaled up. It combines the catalyst and carbon source during high temperature deposition and enables continuous nucleation and growth of CNTs and can be applied to a variety of uneven substrate geometries. However, for a metallic or carbon substrate, an oxidized outer layer is needed on the surface for nucleation of uniformly distributed nanocatalyst particles that will start to grow individual nanotubes instead of carbon clusters. Since this technique requires an oxygenated surface layer, different approaches of creating an oxidized layer on copper sheet samples prior to CVD growth may be considered. These methods produce silicon dioxide on copper. Other methods may be used to deposit other oxides, e.g., aluminum oxide. In some embodiments, an oxide layer (e.g., an intermediate layer or a catalyst layer) may include silicon dioxide and/or aluminum dioxide, and may include thicknesses approximately in the 1-50 nm range (e.g., approximately in the 10 nm to 20 nm range). In some embodiments, an intermediate layer (e.g., catalyst layer) to promote growth of aligned nanostructures on different substrate materials may include other oxide compositions of varying thicknesses depending on substrate materials. In some embodiments, coating a substrate in an intermediate layer (e.g., catalyst layer) may include using at least one of plasma deposition, liquid deposition, atomic layer deposition (ALD), sol-gel deposition, or chemical vapor deposition (CVD). In some embodiments, coating a substrate in an intermediate layer (e.g., catalyst layer) may include using at least one of evaporation, sputtering, epitaxial growth, pulsed laser deposition, e-beam evaporation, or physical vapor deposition.

In some embodiments, main methods of depositing a layer of silicon dioxide on a copper substrate are or comprise the following:
(i) Oxidation by acid: At room temperature, a copper plate was first cleaned with methanol and deionized (DI) water. The cleaned copper sample was immersed into diluted nitric acid solution for 1 min, then removed from solution and rinsed with DI water and left in a fume hood for drying.
(ii) Oxidation by alkali: A copper sample is first cleaned with methanol and DI water. A bath solution is prepared with sodium hydroxide (NaOH) and trisodium phosphate (Na₃PO₄), 5 g of NaOH and 2 g of Na₃PO₄ are mixed with a stirrer in 100 ml DI water. The prepared transparent etch solution was then heated up to 95° C., the copper plate is left in the solution for 30 min at 95° C., then removed from the solution and rinsed with DI water, and air dried in a fume hood.
(iii) Sol-gel deposition of silicon dioxide: A silica precursor solution was prepared by mixing tetraethyl orthosilicate (TEOS), ethanol (EtOH), and water (H₂O) in the volumetric ratios of 1:5:5, respectively. The initial mixtures were mixed thoroughly for 1 h followed by adjusting the pH to 3.0 by adding HCL. The solution was further mixed for 1 h until it became colorless and clear. Copper substrates were soaked in this precursor solution for 1 hr and then air-dried for 12 hrs. Further drying was carried out on hot plate at 100° C., followed by a 2 hr annealing at 500° C. in inert environment.
(iv) Microwave plasma deposition of silicon dioxide: The copper sample was exposed to a mixture of hexa-methyldisiloxane (HMDSO) and high purity oxygen. The plasma cycle consisted of three steps: 1) etching with oxygen, 2) deposition with HMDSO and oxygen, and 3) stabilization with oxygen at ambient temperature. In some cases, multiple coating cycles may be used to create thicker layers of amorphous silica.

In some embodiments, surface etching/activation with oxygen step may occur at about 225 W power for about 180 s. The silica layer deposition step may use oxygen (flow rate about 48 ml/min) and HMDSO (flow rate about 2 ml/min) sent into the reactor simultaneously at about 300 W power for about 300 s. The stabilization step may occur in an oxygen environment at 150 W for 60 s. In some embodiments, this cycle may result in a thin layer of —SiO₂— molecular groups attached on all open surfaces.
(v) Two cycles of plasma deposition: A fifth approach was also used, using the same method as in (iv), but with two cycles of plasma deposition. In some embodiments, provided methods include at least two cycles of plasma deposition (e.g., 3, 4, 5, 6, 7, 8, 9, 10 or more cycles). In some embodiments, provided methods include different plasma power settings and plasma durations.

Comparison of CNT growth on 0.68 mm thick copper sheets was used to identify the most effective method. It was observed that method (v) led to the most uniform CNT growth, and was then used for all final studies. It was subsequently used to grow CNT layers on commercial copper heatsinks (40×40×10 mm, pure copper skived fin HS supplied by GC Thermal).

In some embodiments, after surface oxidation, FC-CVD to grow a layer of vertically aligned CNTs (i.e., where the axes of the CNTs are substantially parallel to each other and oriented normal to the surface of the substrate) can be performed using a three-zone programmable thermal furnace, samples coated with silica layer were first slowly heated up to 700° C. under Ar environment, then the growth was carried out at 700° C. for 3 hours with xylene as carbon source and ferrocene as catalyst, followed by cooling down to room temperature under inert environment.

In some embodiments, nanostructures (e.g., nanoscaled attachments, nanomaterials) may be strongly attached (e.g., covalently attached) to the intermediate layer coating the substrate, and the nanostructures may include nanotubes of ceramic compounds such as nitrides and oxides, carbon nanotubes coated with nitrides and oxides, or nanoparticles of metals and ceramics.

In some embodiments, nanostructures (e.g., CNTs) are strongly (e.g., covalently) bonded to the substrate surface after growth, and are strong enough to survive harsh service conditions such as high speed rotation in water and flowing water (e.g., strong enough to survive 60 rpm to 150 rpm rotation speed in water).

### Characterization of CNT Films

Structural Imaging: Micro-structural images of CNT/copper hierarchical architectures were obtained using a Zeiss n Vision 40 field emission scanning electron microscope (FE-SEM). In order to obtain clear edge-on images of the solid, copper films were sputter-deposited on cleavable silicon surfaces. After CVD growth of CNT, they could be cleaved from the silicon side and directly imaged by SEM without additional sample processing that may introduce artifacts.

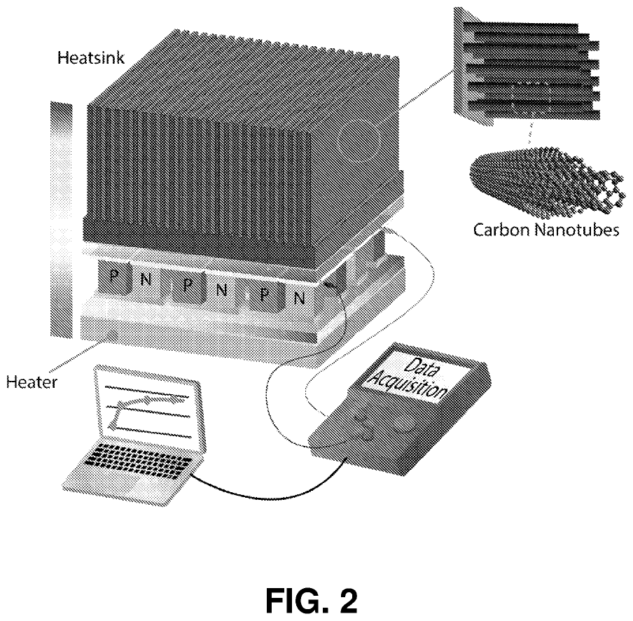

Evaluation of cooling capacity: In order to compare the heat transfer rates of different materials, they were attached to a 40 mm×40 mm×4 mm thermoelectric generators (TCS Systems, Scotland) with their hot sides placed on a micro-heater of the same size, as shown in FIG. 2. Thermal grease (MG Chemicals, non-silicone) was applied between the TEG and heat sink, and the output voltage from the TEG measured with the heater set at 100° C. FIG. 2 is a schematic diagram illustrating a hierarchical hybrid nanomaterial heat sink structure and measurement setup, according to aspects of the present embodiments. FIG. 2 shows an exemplary heat sink made of a conductive metal (e.g., copper) with multiple fins (e.g., thin, parallel plates). In some embodiments, an array of nanostructures (e.g., carbon nanotubes) may be attached to outer surfaces of the heat sink, and may be vertically aligned with respect to the surfaces of the heat sink (i.e., extending normally outward from the surfaces of the heat sink, and the nanotubes aligned parallel to each other). In some embodiments, the carbon nanotubes may include single-walled carbon nanotubes, double-walled carbon nanotubes, multi-walled carbon nanotubes, or a combination of the above types of carbon nanotubes. In some embodiments, the heat sink may be thermally contacted to a cold side of a thermoelectric generator, and a heater may be thermally contacted to a hot side of the thermoelectric generator. In some embodiments, one or more sensors may be contacted to the thermoelectric generator to measure quantities such as temperatures and voltages, and may be connected to a computer for data collection.

### C. Results and Discussion

### Microstructural Analyses of CNT Coating on Copper

Most non-oxide materials such as metals, silicon and carbon need an oxygen containing surface layer for nucleation and growth of CNTs by CVD. Experiments were conducted to identify the simplest and most scalable approach of achieving a suitable oxide catalyst layer on copper. It was observed that among the five approaches tested for creating oxidized layers on the copper surface, the modified 2-layer microwave plasma coating worked the best in terms of uniformity and thickness of CNT growth and was selected for all further studies.

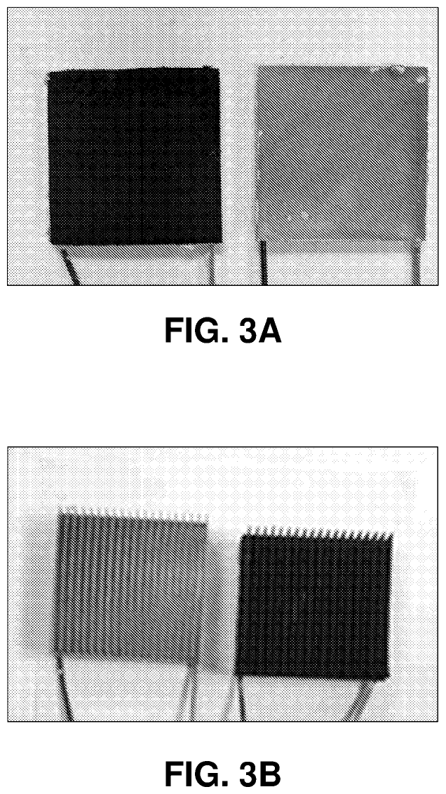

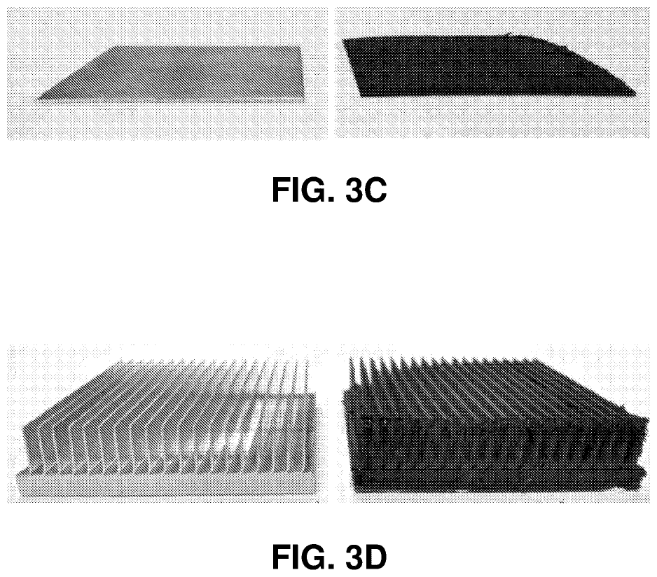

Optical images of copper sheets and commercial heat sinks before and after CNT growth are shown in FIGS. 3A, 3B, 3C, and 3D. These images show that after CNT growth, the surfaces are covered in a very dark, uniform layer but the overall geometry of the copper is unchanged. That is, the CNT layer conformally coats the copper substrates. FIG. 3A is a photograph of a thermoelectric device with flat copper sheet heat sink coated in CNT (left) and a thermoelectric device with flat copper sheet heat sink without CNT coating (right), according to aspects of the present embodiments. FIG. 3B is a photograph of a thermoelectric device with finned copper heat sink without CNT coating (left) and a thermoelectric device with finned copper heat sink coated in CNT (right), according to aspects of the present embodiments. FIG. 3C is a photograph of a copper sheet (left) and a photograph of a copper sheet with CNT coating grown on it (right), according to aspects of the present embodiments. FIG. 3D is a photograph of a commercial copper heat sink with skived fin structure (left), and a photograph of the same heat sink coated with CNT (right), according to aspects of the present embodiments.

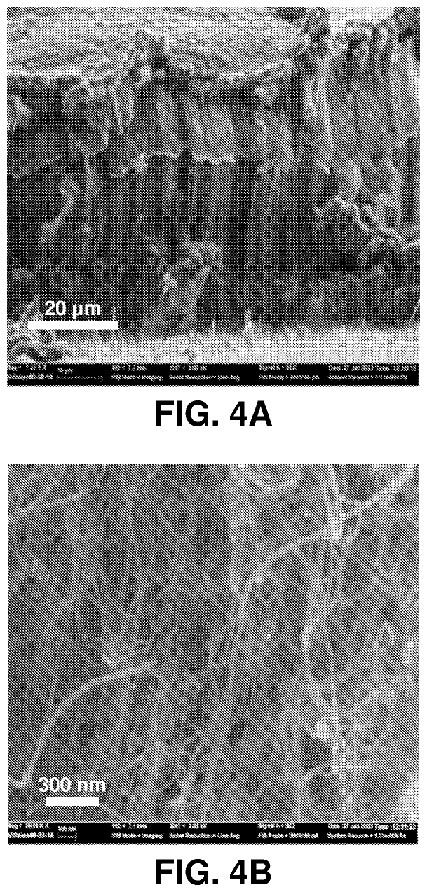

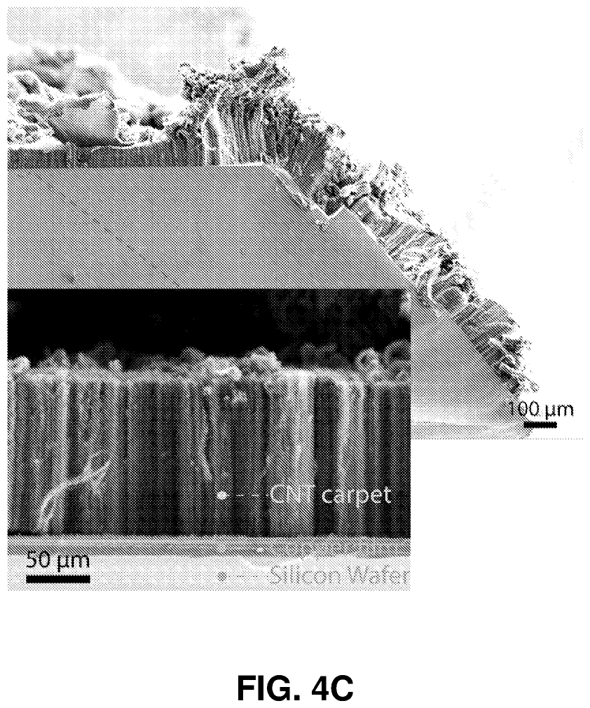

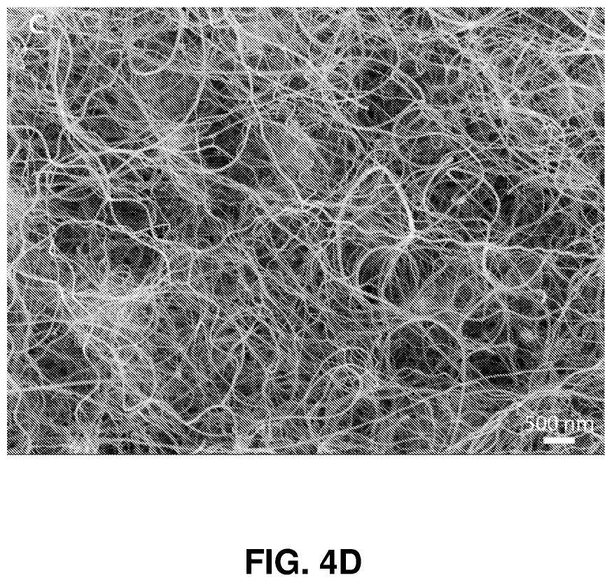

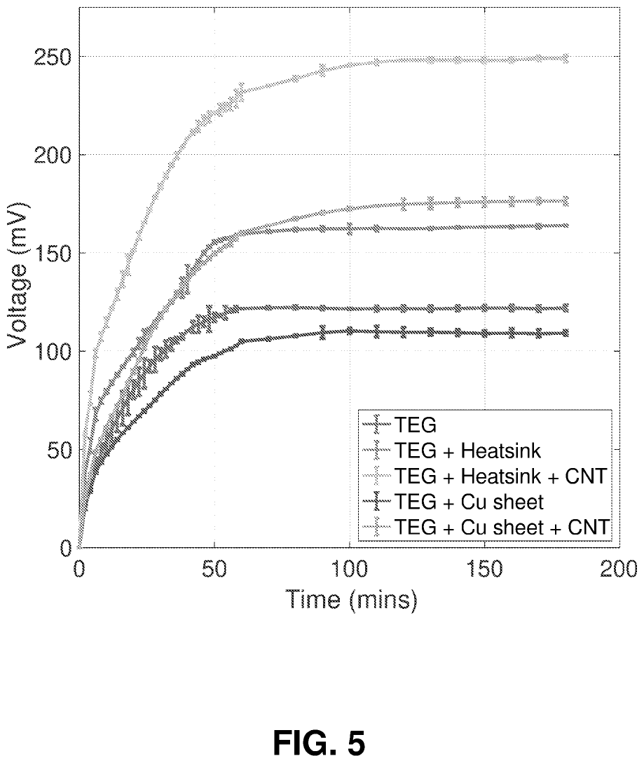

SEM images of the CNT array on copper substrate are shown in FIGS. 4A, 4B, 4C, and 4D. FIG. 4A is a scanning electron microscopy (SEM) image of a CNT coating grown on copper in cross-sectional view at low magnification, according to aspects of the present embodiments. FIG. 4B is a scanning electron microscopy (SEM) image of a CNT coating grown on copper in cross-sectional view at high magnification, according to aspects of the present embodiments. FIG. 4C is a scanning electron microscopy (SEM) image of a side view of a CNT coating grown on a copper film on a silicon wafer (top), and in an enlarged view (bottom) showing substantially aligned CNTs, according to aspects of the present embodiments. FIG. 4D is a scanning electron microscopy (SEM) image of a top view of a CNT coating grown on a copper film showing some degree of CNT entanglement, according to aspects of the present embodiments.

It can be seen from FIG. 4A and FIG. 4C that the FC-CVD method grows continuous, densely packed CNT coatings where the CNTs are arranged in a carpet-like structure from an uneven solid terrain. In FIG. 4C, corners and ridges of the substrate show variations in CNT lengths, as expected, due to changes in substrate morphology and their relative orientation with respect to plasma and vapor flow directions. While the aerial density of the CNT carpet is also expected to vary from location to location for the same reasons, earlier high-resolution studies on model flat surfaces using the same process parameters have indicated an average aerial density of about 1.5×10¹⁰ nanotube strands per square cm of oxide-coated substrate.

FIG. 4C (top) shows that on flat regions of the substrate, the CNT carpet is very uniform, is well aligned normal to the substrate, and that the carpet height exceeds several hundred μm. FIG. 4D shows that there is some CNT entanglement at the top or outer surface of CNT coating, as expected, and that the average outer diameter of the CNT is around 19 (±4) nm.

In some embodiments, based on earlier studies of CNTs grown on carbon substrates, the individual nanotubes may have an inner diameter of about 9.9 (±0.76) nm and outer diameter of 22.4 (±1.84) nm, a thermal conductivity of about 30 W/mK and specific surface area of 99.8 m² g⁻¹. The SEM image in FIG. 4A shows the overall thickness of the CNT array, or the length of the vertically aligned CNTs, is about 50 to about 60 μm. The SEM image in FIG. 4B shows the individual CNTs are substantially aligned vertically (i.e., aligned with their axes perpendicular to the substrate surface), with some portions that are not vertically aligned. In some embodiments, each of the carbon nanotubes comprises an outer diameter between about 5 nm and about 30 nm (e.g., between about 5 nm and 20 nm, between about 10 nm and 40 nm, between about 0.5 nm and 2 nm, between about 0.5 nm and 5 nm), and a length between about 5 μm and 60 μm (e.g., between about 50 μm to about 60 μm, e.g., between about 1 μm to about 100 μm, e.g., between about 1 μm to about 500 μm, e.g., between about 1 μm to about 1000 μm).

### Influence of CNT Coating on Electronic Cooling

FIG. 4 shows a plot of open circuit output voltage vs. time from TEGs with different heat sink arrangements, measured using the experimental setup illustrated in FIG. 1. The TEG device is thermally contacted on its hot side onto a heater, and contacted on its cold side with a heat sink. The heater is turned on and set to 100° C., and the ambient air is 21° C. in all cases. Table 1 summarizes the steady open circuit voltages for each type of heat sink.

TABLE 1
Steady output voltages from TEGs with different types of heat sinks

| Type of heat sink | Heat sink weight | | ΔV (mV) |
|---|---|---|---|
| Bare TEG without any heat sink | 0 | | 121.68 ± 1.17 |
| Plain copper sheet in TEG | 9.446 | g | 111.82 ± 0.88 |
| Copper sheet coated with CNT | 9.488 g (0.5% higher than | | 177.38 ± 0.49 (58.6% |
| array | bare copper sheet) | | higher than bare copper |
| | | | sheet) |
| Commercial heat sink | 64.467 | g | 162.85 ± 1.69 |

| | | |
|---|---|---|
| Commercial heat sink coated | 65.561 g (0.15% higher | 248.69 ± 1.36 (52.7% |
| with CNT array | than bare heat sink) | higher than bare heat |
| | | sink) |

It is observed that adding a plain sheet of copper on the TEG lowers its output voltage slightly, by about 7%. This can be attributed to the thermal grease applied between the TEG and copper sheet creating an extra interface with added thermal resistance, and any difference in emissivity between the TEG and copper surfaces. There may also be a contribution from reduced air flow on the cold side that prevents passive convective heat transfer. However, when this same copper sheet is coated with CNTs, the output voltage is increased by 59%, to a value higher than even that from a commercial copper heat sink with fins. This experiment indicates that a 65 g flat pin heat sink can be replaced by 9.5 g of Cu-CNT hybrid material for the same cooling effect. Adding the CNT layer on the commercial heat sink further enhances cooling rate to increase TEG voltage by 52.7% compared to a bare HS, with less than 0.2% increase in weight. In comparison to bare TEG without HS, this CNT-HS-TEG combination shows a 104% increase in output voltage.

These experiments clearly indicate that, in some embodiments, the addition of a CNT layer on copper enhances its cooling capacity significantly, irrespective of the heat sink architecture. TEG performance enhancement is well over 50% for two different structures tested, of a flat sheet of copper as well as a prefabricated plate-fin heat sink. In some embodiments, HS performance can be increased by controlling CNT densities, lengths, directions, and/or infiltrating these nanostructures with a variety of coolants.

Experiments on heat sinks tested at 100° C. with repeated temperature cycling showed the heat sink and CNT architectures and thermal properties were maintained, while the TEG also operates normally after repeated two hours of heating and cooling cycles for more than 20 cycles.

The heat transfer performance of the CNT-coated copper heat sinks were also measured while keeping the hot side at 180° C. to ascertain their effectiveness at higher temperatures. The open circuit output voltage was measured as before, but also the temperature at the cold side was directly measured during the entire cycle. These variables were measured electronically at the same time by taking temperature and voltage recordings simultaneously. Table 2 shows experimental results from TEGs heated from room temperature (24° C.) up to 180° C. and held at 180° C. over 3 hours.

TABLE 2
Voltage output and cold side temperatures
of heat sinks at steady state (T_{H} = 180 C.)

| | Output | Cold Side | Change in |
|---|---|---|---|
| | Voltage | Temperature | Temperature |
| Substrate | (V) | (° C.) | (° C.) |
| TEG | 283 | 169 | 13 |
| Copper Sheet + CNT | 334 | 156 | 25 |
| Copper Heat Sink | 391 | 158 | 24 |
| Copper Heat Sink + | 433 | 148 | 34 |
| CNT | | | |
| Copper Sheet | 257 | 174 | 8 |

It was observed that the open circuit output voltage continued to significantly increase when CNTs are attached to the heat sink. There is also a consistent relationship between the open circuit voltage and temperature.

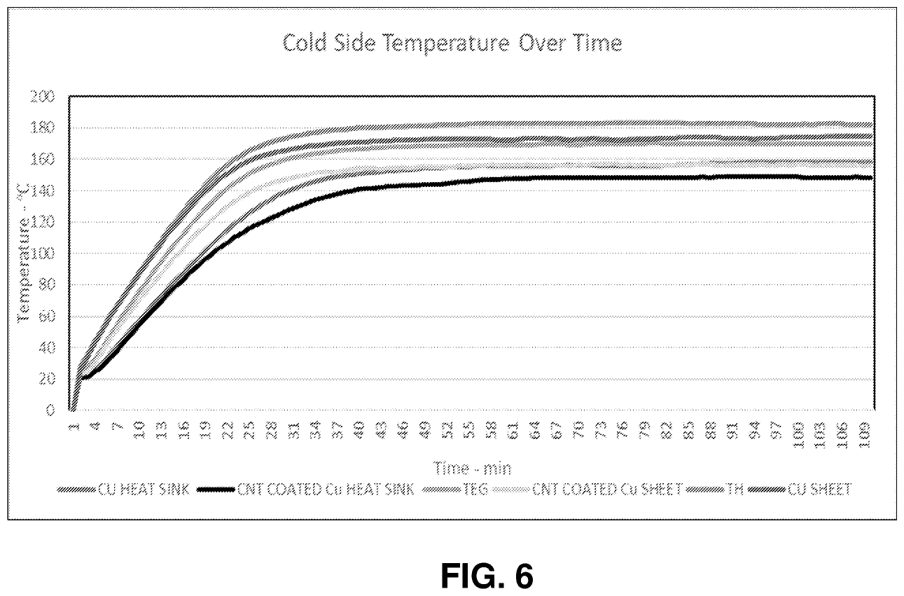

FIG. 6 shows a plot of cold side temperatures on a TEG for different heat sink arrangements when T_{H} is maintained at 180° C., according to aspects of the current embodiments. The plot shows the lowest cold side temperature is achieved with a Cu heat sink coated in CNTs, with the temperature just below about 150° C. In comparison, the heat sink alone is at about 160° C., a bare copper sheet is at about 170° C., and a CNT-coated copper sheet is at about 150° C.

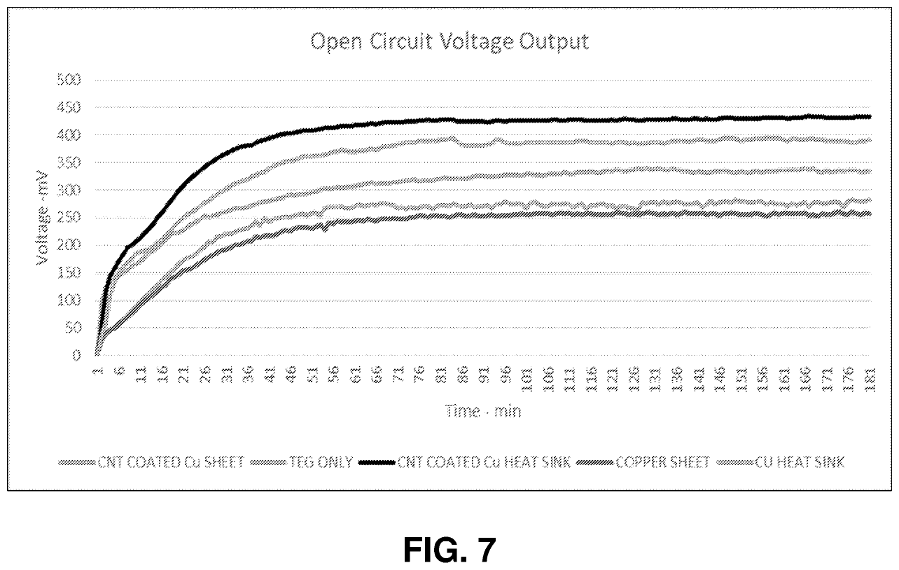

FIG. 7 shows a plot of open circuit voltage output from a TEG with different heat sink arrangements when T_{H} is maintained at 180° C., according to aspects of the current embodiments. The plot shows the highest open circuit voltage for a TEG with a CNT-coated heat sink, reaching about 430 mV. In comparison, the TEG with a heat sink alone reaches about 390 mV, with a CNT-coated Cu sheet about 335 mV, and with a bare Cu sheet about 250 mV.

Previous computational and experimental studies reported heat sink improvements through fin shape contouring, fin perforations, surface grooving, as well as the introduction of coolants such as water, phase change materials and nanofluids and such techniques are compatible with various embodiments. For cooling of TEGs, improved fin design showed passive cooling improvements of about 6-7%. For active cooling using nanofluid circulation, experimental results reported 10-20% improvement, and computational models predicted up to 40% possible enhancement.

The performance of the CNT-coated heat sinks of the present embodiments are compared to other types of active and passive cooling of TEG in Table 3. While the TEG design and testing of each study is different, the percentage change in output caused by heat sink improvement has been shown in the table. It is observed that the hierarchical hybrid architecture of the present embodiments demonstrates a TEG output increase by 50% even in the passive mode tested. It must be noted that this improvement can be further enhanced with additional nanostructure optimization and active cooling additions.

TABLE 3
Open circuit voltage comparison

| | Percentage output | |
|---|---|---|
| Cooling system | increase at 100° C. | Reference |
| Commercial heat sink enhanced with | 52.7% w.r.t commercial finned HS | Present |
| strongly bonded CNT carpet | 102% w.r.t no HS | embodiments |
| (Passive cooling) | | |
| Heat sink with altered fin arrangement | 6.1% | Boccardi et al. |
| (Passive cooling) | w.r.t regular commercial finned HS | |
| CNT-PDMS composite with fan | 40% w.r.t no HS | Yildiz et al. |
| (Active cooling) | | |
| Cooling with a nanofluid - graphene | 11.29% | Li et al. |
| wire (CNT) added to water | w.r.t. pure water cooling | |
| (Active cooling with water) | | |
| Water-film evaporative pond | 18.1% | Zheng et al. |
| (Active cooling through evaporation) | w.r.t. commercial finned HS | |
| Finned heatsink with perforations or | ~13% without air flow | Huang et al. |
| mini channels | ~41% predictive model with air | |
| (Experiments and models) | flow | |
| | Both w.r.t. commercial finned HS | |

w.r.t. = with respect to

The present disclosure provides scope for further improvements in this design to boost the HS capability. One approach would be to tailor the CNT morphology by altering the CNT spacing and length on heat spreader substrates. It is expected that on one hand, more nanotubes of longer length may increase the overall surface area between CNT and surrounding fluid for increased heat exchange. However, longer and denser CNT may restrict fluid flow, and hence reduce the convection heat transfer coefficient, h, in equation 6. More detailed investigation is being performed to understand individual heat transfer mechanisms and analyze the influence of CNT morphology, distribution parameters, and surface treatments on cooling effectiveness, and will be reported in future papers.

In some embodiments, additional enhancement of the heat sink performance will be possible by the addition of active coolants. By way of non-limiting example, for liquid coolants, the CNT surface can be functionalized for improved wettability and infiltration of the liquid. In that case, longer CNT carpets may significantly increase heat transfer rates. One question that will come up for forced cooling application (air or liquid) will be the maximum fluid speeds the CNT carpets can sustain during service. While fluid speed tests have not yet been performed on these materials, few other materials with similar CNT design have been tested in severe water agitation conditions and the CNT layer was observed to be durable. Future studies are being planned to answer these questions for specific heat sink architectures.

In some embodiments, the present disclosure is directed to a method to fabricate hybrid carbon nanotube and copper heat sink structures, including the steps of providing a copper substrate; depositing a layer of oxide on an exterior surface of the copper substrate using microwave plasma; and conducting chemical vapor deposition (CVD) in a CVD chamber using the copper substrate.

In some embodiments, the present disclosure is directed to a composition including a hybrid carbon nanotube and copper heat sink structure, including: a copper substrate; a layer of carbon nanotubes covalently attached to an external surface of the copper substrate, comprising vertically aligned carbon nanotubes, wherein each carbon nanotube comprises a diameter between about 5 nm and about 20 nm, and a length between about 5 μm and about 50 μm, and wherein each carbon nanotube is covalently attached at one end to the external surface of the copper substrate.

In some embodiments, various embodiments of the present disclosure may be used to cool any electronic devices, for example processors, CPUs, GPUs, chipsets, RAM modules, lasers, LEDs, batteries, photovoltaics, computers, chips, power electronics, motors, engines, actuators, mobile devices, tablets, mobile phones, automobiles, vehicles, etc. In some embodiments, the present disclosures may be applied to heat sinks, heat spreaders, thermoelectric generators, thermoelectric coolers, and other devices.

### D. References

M. A. Abdelkareem et al., Prospects of TE generators with nanofluids, Thermal Science and Engineering Progress 29 (2022) 101207.
H. E. Ahmed, B. H. Salman, A. S. Kherbeet, M. I. Ahmed, Optimization of thermal design of heat sinks: A review, Int J Heat Mass Transf. 118 (2018) 129-153.
S. Boccardi, F. Ciampa, M. Meo, Design and development of a heatsink for thermo-electric power harvesting in aerospace applications, Smart Mater Struct. 28 (2019) 105057.
B. A. Cola, J. Xu, C. Cheng, X. Xu. T. S. Fisher, H. Hu, Photoacoustic characterization of carbon nanotube array thermal interfaces, J Appl Phys. 101 (2007) 054313.
D. J. R. Davis. ASM Specialty Handbook, Copper and Copper Alloys, ASM Handbook. (2001) 133. ISBN: 978-0-87170-726-0.
F. Daneshvar, H. Chen, K. Noh, and H. J. Sue. Critical challenges and advances in the carbon nanotube-metal interface for next generation electronics. Nanoscale Adv. 2021, 3, 942-962.
A. Elghool, F. Basrawi, H. Ibrahim, T. K. Ibrahim, M. Ishak, T. M. Yusof, S. A. Bagaber, Enhancing the performance of a thermo-electric generator through multi-objective optimisation of heat pipes-heat sink under natural convection. Energy Convers Manag. 209 (2020) 112626.
D. Enescu, D. Enescu, Thermoelectric Energy Harvesting: Basic Principles and Applications, Green Energy Advances. (2019).
S. Feng, M. Shi, H. Yan, S. Sun, F. Li, T. J. Lu, Natural convection in a cross-fin heat sink, Appl Therm Eng. 132 (2018) 30-37.
X. L. Gou, H. Xiao, S. Yang, “Modeling, experimental study and optimization on low-temperature waste heat thermoelectric generator system,” Applied Energy, Elsevier, vol. 87 (10), pages 3131-3136 October 2010.
S. Huang. W. Li, D. Xu, X. Sui, Y. Zhang, Theoretical and Experimental Study of the Effect of Mini Channel Finned Heatsink on Thermoelectric Generator Performance in Air-Cooled Environment, J Therm Sci Eng Appl. 14 (2022).
T. K. Ibrahim. A. T. Al-Sammarraie, M. S. M. Al-Jethelah, W. H. Al-Doori, M. R. Salimpour, H. Tao, The impact of square shape perforations on the enhanced heat transfer from fins: Experimental and numerical study, International Journal of Thermal Sciences. 149 (2020).
T. K. Ibrahim, A. T. Al-Sammarraie. W. H. Al-Taha, M. R. Salimpour, M. Al-Jethelah. A. N. Abdalla, H. Tao, Experimental and numerical investigation of heat transfer augmentation in heat sinks using perforation technique, Appl Therm Eng. 160 (2019) 113974.
A. Karumuri, L. He and S. M. Mukhopadhyay, “THning the Surface Wettability of Carbon Nanotube Carpets in Multiscale Hierarchical Solids”, Applied Surface Science, 327 (2015) 122-130.
A. K. Karumuri, D. P. Oswal, H. A. Hostetler, S. M. Mukbopadhyay, Silver nanoparticles attached to porous carbon substrates: robust materials for chemical-free water disinfection. Mater Lett. 109 (2013) 83-87.
H. S. Kim, W. Liu, G. Chen, C. W. Chu, Z. Ren, Relationship between thermoelectric figure of merit and energy conversion efficiency, Proc Natl Acad Sci USA. 112 (2015) 8205-8210.
Y. H. Li et al. Study on the performance of TEG with heat transfer enhancement using graphene-water nanofluid for a TEG cooling system. Sci China Tech Sci, 2017, 60:1168-1174.
Y. R. Li, C. P. Huang; C. C. Su, S. H. Chang, Ultrafast Patterning Vertically Aligned Carbon Nanotube Forest on Al Foil and Si Substrate Using Chemical Vapor Deposition (CVD). Nanomaterials 2019, 9, 1332.
W. Lin, R. Zhang, K. S. Moon, C. P. Wong, Synthesis of high-quality vertically aligned carbon nanotubes on bulk copper substrate for thermal management, IEEE Transactions on Advanced Packaging. 33 (2010) 370-376.
A. D. Manasrah, et al., Surface modification of carbon nanotubes with copper oxide nanoparticles for heat transfer enhancement of nanofluids, RSC Adv., 2018, 8, 1791-1802.
A. D. Manasrah, I. W. Almanassra, N,N. Marei, U. A. Al-Mubaiyedh, T. Laoui, M. A. Atieh, Surface modification of carbon nanotubes with copper oxide nanoparticles for heat transfer enhancement of nanofluids, RSC Adv. 8 (2018) 1791-1802.
S. M. Mukhopadhyay, A. Karumuri and I. T. Barney, “Hierarchical nanostructures by nanotube grafting on porous cellular surfaces”, J. Phys. D: Appl. Phys. 42 (2009).
S. M. Mukhopadhyay, A. Karumuri, I. T. Barney, Hierarchical nanostructures by nanotube grafting on porous cellular surfaces, J Phys D Appl Phys. 42 (2009) 195503.
R. V. Pulikollu, S. M. Mukhopadhyay, Nanoscale coatings for control of interfacial bonds and nanotube growth, Appl Surf Sci. 253 (2007) 7342-7352.
R. Que, W. Ding. S. Sba, A Simple, Facile Demonstration of Copper and Nitric Acid Reaction, J Chem Educ. 99 (2022) 2762-2765.
B. T. Quinton, L. Elston, J. D. Scofield and S. M. Mukhopadhyay, “Aligned Carbon Nanotube Arrays Bonded to Solid Graphite Substrates: Thermal Analysis for Future Device Cooling Applications”, Journal of Carbon Research, 2018, 4, 28.
B. T. Quinton, Q. Zhang, J. Burke, K. Leedy, B. Tsao, J. Scofield, J. N. Merrett, K. Yost, S. M. Mukhopadhyay, “The Effects of Surface Treatments on the Growth of CNTs on 3-Dimensional Carbon Foam Structure”, Nanotech 2013 Vol. 1, 10, Nanoscience & Technology Institute, 2013.
D. M. Rowe, “Thermoelectrics Handbook: Macro to Nano.” CRC Press (2018).
M. Sajid, I. Hassan, A. Rahman, An overview of cooling of thermoelectric devices, Renewable and Sustainable Energy Reviews. 78 (2017) 15-22.
M. R. Saffarian, M. Moravej. M. H. Doranehgard, Heat transfer enhancement in a flat plate solar collector with different flow path shapes using nanofluid. Renew Energy. 146 (2020) 2316-2329
A. Schlott, T. Hutsch, S. Hampel, J. Lohse, T. Weißgärber & B. Kieback, (2019). Heat exchange structures based on Copper/CNT composite. Key Engineering Materials, 809, 106-114.
J. L. Smoyer and P. M. Norris. Brief Historical Perspective in Thermal Management and the Shift Toward Management at the Nanoscale. Heat Transf. Eng. 2019; 40:269-282.
A. Thapa, S. Neupane, R. Guo, K. L. Jungjohann, D. Pete, W. Li, Direct growth of vertically aligned carbon nanotubes on stainless steel by plasma enhanced chemical vapor deposition, Diam Relat Mater. 90 (2018) 144-153.
A. Venkataraman, E. V. Amadi, Y. Chen, C. Papadopoulos, Carbon Nanotube Assembly and Integration for Applications, Nanoscale Res Lett. 14 (2019).
H. Wang, J. Feng, X. Hu. K. M. Ng. Synthesis of Aligned Carbon Nanotubes on Double-Sided Metallic Substrate by Chemical Vapor Deposition, Journal of Physical Chemistry C. 111 (2007) 12617-12624.
W. Wang. S. M. Mukhopadhyay, Hierarchical nanostructured surface design for robust and flexible multifunctional devices, Carbon Trends. 5 (2021) 100096.
J. J. Xing, Z. H. Wu. H. Q. Xie, Y. Y. Wang, Y. H. Li, J. H. Mao, Performance of thermoelectric generator with graphene nanofluid cooling, Chin. Phys. B 26 (2017), 104401.
X. Yin, Q. Wang. C. Lou, X. Zhang, W. Lei, Growth of multi-walled CNTs emitters on an oxygen-free copper substrate by chemical-vapor deposition, Appl Surf Sci. 254 (2008) 6633-6636.
O. Yildiz, M. M. Lubna, V. P. Ramesh, M. Ozturk, P. D. Bradford, Microporous vertically aligned CNT nanocomposites with tunable properties for use in flexible heat sinks, Journal of Science: Advanced Materials and Devices 7 (2022) 100509.
G. Zhang, S. Jiang, H. Zhang. W. Yao, C. Liu, Excellent heat dissipation properties of the super-aligned carbon nanotube films, RSC Adv. 6 (2016) 61686-61694.
S. Zhang, W. E. Lee, Improving the water-wettability and oxidation resistance of graphite using Al2O3/SiO2 sol-gel coatings, J Eur Ceram Soc. 23 (2003) 1215-1221.
L. J. Zheng, S. Lim, N. K. Kim, D. H. Kang, Y. J. Youn, W. Lee, H. W. Kang, Experimental study of a thin water-film evaporative cooling system to enhance the energy conversion efficiency of a thermoelectric device. Energy. 211 (2020) 119040

What is claimed:

1. A multilayer structure comprising:
a substrate;
an intermediate layer coating a surface of the substrate; and
a plurality of nanoscale attachments attached to the intermediate layer or to the surface of the substrate.

2. The multilayer structure of claim 1, wherein the substrate comprises a material with high thermal conductivity (e.g., above 10 W m⁻¹ K⁻¹, above 50 W m⁻¹ K⁻¹, above 100 W m⁻¹ K⁻¹).

3. The multilayer structure of claim 1, wherein the substrate comprises a metal (e.g., copper, aluminum, brass).

4. The multilayer structure of claim 1, wherein the substrate comprises a ceramic (e.g., aluminum nitride, beryllium oxide, aluminum oxide, diamond, silicon carbide, silica).

5. The multilayer structure of claim 1, wherein the substrate comprises at least one of a sheet, a porous structure, a block, a heat sink, a heat spreader, a wire, a rod, foil, a mesh, or a tube.

6. The multilayer structure of claim 1, wherein the substrate comprises a heat sink, wherein the heat sink comprises one or more fins and/or one or more pins for heat dissipation.

7. The multilayer structure of claim 1, wherein the plurality of nanoscale attachments comprise carbon nanotubes.

8. The multilayer structure of claim 7, wherein the carbon nanotubes are arranged in a substantially vertically aligned array, wherein each of the carbon nanotubes is strongly (e.g., covalently) attached at one end to a location on the intermediate layer or on the substrate, and wherein the axes of the carbon nanotubes are aligned substantially normal to the substrate surface at the location of attachment.

9. The multilayer structure of claim 7, wherein each of the carbon nanotubes comprises an outer diameter between about 5 nm and about 30 nm (e.g., between about 5 nm and 20 nm, between about 10 nm and 40 nm, between about 15 nm and 30 nm, between about 0.5 nm and 2 nm, between about 0.5 nm and 5 nm), and a length between about 5 μm and 60 μm (e.g., between about 50 μm to about 60 μm, between about 1 μm to about 100 μm, between about 1 μm to about 500 μm, between about 1 μm to about 1000 μm).

10. The multilayer structure of claim 1, wherein the plurality of nanoscale attachments are strongly (e.g., covalently) bonded to the intermediate layer.

11. The multilayer structure of claim 7, wherein the carbon nanotubes comprise an average areal density of about 1.5×10¹⁰ nanotubes per square centimeter (e.g., about 10⁹ nanotubes per cm², about 10¹⁰ nanotubes per cm², about 5×10¹⁰ nanotubes per cm², about 10¹¹ nanotubes per cm², between about 5×10⁹ nanotubes per cm² and about 5×10¹⁰ nanotubes per cm²).

12. The multilayer structure of claim 1, wherein the intermediate layer comprises an oxide.

13. The hybrid structure of claim 12, wherein the oxide comprises silicon dioxide or aluminum oxide.

14. The hybrid structure of claim 12, wherein the oxide layer is between about 10 nm and 20 nm thick (e.g., between about 5 nm and 10 nm, between about 5 nm and 20 nm, between about 10 nm and 40 nm, below about 50 nm, between about 1 nm and 100 nm).

15. A method of fabricating a multilayer structure, comprising:
providing a substrate;
preparing an outer surface of the substrate using one or more surface treatments;
at least partially coating the outer surface with an intermediate layer to form a coated surface; and
depositing a plurality of nanoscale attachments onto the coated surface.

16. The method of claim 15, wherein the one or more surface treatments comprises cleaning, treating, and/or activating using ions, acids, alkalis, plasmas, and/or solvents.

17. The method of claim 15, wherein the plurality of nanoscale attachments comprise carbon nanotubes.

18. The method of claim 17, wherein the carbon nanotubes are arranged in a substantially vertically aligned array, wherein each of the carbon nanotubes is strongly (e.g., covalently) attached at one end to the outer surface of the intermediate layer.

19. The method of claim 15, wherein coating the outer surface comprises using at least one of plasma deposition, liquid deposition, atomic layer deposition (ALD), sol-gel deposition, or chemical vapor deposition (CVD).

20. The method of claim 15, wherein depositing the plurality of nanoscale attachments comprises using at least one of plasma deposition, liquid deposition, atomic layer deposition (ALD), or chemical vapor deposition (CVD).

21. The method of claim 19, wherein method further comprises heating the substrate in a controlled environment.

22. The method of claim 20, wherein the method further comprises heating the substrate in a controlled environment.

23. The method of claim 15, wherein the intermediate layer comprises an oxide.

24. The method of claim 23, wherein the oxide comprises silicon dioxide or aluminum oxide.

25. The method of claim 15, wherein the nanoscale attachments comprise at least one of nanotubes of ceramics, nanotubes of nitrides, nanotubes of oxides, carbon nanotubes coated with nitrides and/or oxides, or nanoparticles of metals and/or ceramics.

26. The method of claim 15, wherein the substrate comprises a material with high thermal conductivity (e.g., above 10 W m⁻¹ K⁻¹, above 50 W m⁻¹ K⁻¹, above 100 W m⁻¹ K⁻¹).

27. The method of claim 26, wherein the material comprises a metal (e.g., copper, aluminum, brass).

28. The method of claim 26, wherein the material comprises a ceramic (e.g., aluminum nitride, beryllium oxide, aluminum oxide, diamond, silicon carbide, silica).

29. The method of claim 15, wherein the substrate comprises at least one of a sheet, a porous structure, a block, a heat sink, a heat spreader, a wire, a rod, foil, a mesh, or a tube.

30. The method of claim 15, wherein the plurality of nanoscale attachments forms a continuous, conformal layer.

31. The method of claim 20, wherein depositing comprises using floating catalyst chemical vapor deposition (FC-CVD).

32. The method of claim 31, wherein FC-CVD is conducted using a three-zone programmable thermal furnace, comprising the steps of:
heating the substrate after coating with a silica layer to 700° C. under inert gas (e.g., Ar gas environment);
growing carbon nanotubes at 700° C. for 3 hours with xylene as a carbon source and ferrocene as a catalyst; and
cooling down to room temperature under inert gas (e.g., Ar gas environment).

33. The method of claim 15, wherein the substrate comprises copper.

34. The method of claim 15, wherein coating the outer surface comprises microwave plasma deposition, comprising the steps of:
etching the substrate with oxygen;
depositing silica using a mixture of hexa-methyldisiloxane (HMDSO) and oxygen; and
stabilizing with oxygen.

35. The method of claim 34, wherein etching the substrate occurs at 225 W power for 180 s, wherein depositing silica occurs at 300 W power for 300 s, wherein depositing silica occurs with HMDSO flowing at 2 ml/min and oxygen flowing at 48 ml/min, and wherein stabilizing with oxygen occurs at ambient temperature and 150 W power for 60 s.

36. The method of claim 34, wherein the steps of claim 34 are repeated for a total of two cycles (e.g., three cycles, four cycles, five cycles).

37. A method of cooling a structure to be cooled, comprising thermally contacting a surface of the structure with a multilayer structure according to any one of claims 1-14.

38. The method of claim 37, wherein the method further comprises flowing a fluid around the plurality of nanoscale attachments.

39. The method of claim 38, wherein the fluid comprises at least one of air, water, gas, solvent, coolant, or nanofluid.

40. The method of claim 38, wherein flowing the fluid comprises forcing the fluid to flow.

41. The method of claim 37, wherein the structure to be cooled comprises at least one of a thermoelectric generator, a processor, a central processing unit (CPU), a GPU, a chipset, a random access memory (RAM) module, a laser, a light emitting diode (LED), a battery, a photovoltaic, a computer, a chip, a power electronic module, a thermoelectric cooler, a motor, an engine, an actuator, a mobile device, a tablet, a mobile phone, a part of an automobile, or a part of a vehicle.

42. The method of claim 37, wherein the method further comprises applying a layer of a thermally conductive interface between the structure to be cooled and the multilayer structure, wherein the thermally conductive interface comprises at least one of a thermal paste, a thermal compound, a thermal grease, a thermal interface material, a thermal gel, a heat paste, a heat sink compound, a heat sink paste, or a CPU grease.

43. A system comprising:
a structure to be cooled; and
a multilayer structure according to any one of claims 1-14,
wherein the multilayer structure is configured to be in thermal contact with the structure to be cooled.

44. The system of claim 43, wherein the structure to be cooled comprises at least one of a thermoelectric generator, a processor, a central processing unit (CPU), a GPU, a chipset, a random access memory (RAM) module, a laser, a light emitting diode (LED), a battery, a photovoltaic, a computer, a chip, a power electronic module, a thermoelectric cooler, a motor, an engine, an actuator, a mobile device, a tablet, a mobile phone, a part of an automobile, or a part of a vehicle.

45. The system of claim 43, wherein the system further comprises a fluid that flows around the plurality of nanoscale attachments, wherein the fluid comprises at least one of air, water, gas, solvent, coolant, or nanofluid.

46. The system of claim 43, wherein the system further comprises a thermally conductive interface layer disposed between the structure to be cooled and the multilayer structure, wherein the thermally conductive interface layer comprises at least one of a thermal paste, a thermal compound, a thermal grease, a thermal interface material, a thermal gel, a heat paste, a heat sink compound, a heat sink paste, or a CPU grease.

47. The system of claim 44, wherein the thermoelectric generator is thermally contacted by the multilayer structure on a cold side of the thermoelectric generator, and wherein the thermoelectric generator is configured to thermally contact the structure to be cooled on a hot side of the thermoelectric generator.
